(19) United States
(12) Patent Application Publication
(10) Pub. No.: US 2002/0130716 A1
(43) Pub. Date: Sep. 19, 2002

(54) Linearization circuit and technique for a power combining network, or diplexer; especially as may use high temperature superconducting filters

(76) Inventors: Lawrence Larson, Del Mar, CA (US); Robert Hammond, Santa Barbara, CA (US); Balam Willemsen, Ventura, CA (US); David Chase, Santa Barbara, CA (US); Peter Asbeck, San Diego, CA (US)

Correspondence Address: FUESS & DAVIDENAS, Suite II-G, 10951 Sorrento Valley Road, San Diego, CA, 92121-1613, US

(21) Appl. No.: 09/808,908

(22) Filed: Mar. 14, 2001

(51) Int. Cl. H03F 1/26

(52) U.S. Cl. 330/151

(57) ABSTRACT

In a reduced-distortion bandpass filtering circuit, and method, a small portion, normally −20 db, of an input signal, normally narrowband rf, is fed forward while a major signal portion is filtered in a first bandpass filter, inducing distortion. The small portion fed forward is itself bandpass filtered in a second bandpass filter, preferably identical to the first. Because the signal level is lower, less distortion is produced. The second-bandpass-filtered small portion is subtracted from yet another small, −20 db, portion now fed forward from the first-bandpass-filtered signal, distortion and all. Undistorted parts of the two signals cancel, isolating the signal distortion. This distortion is amplified and adjusted in phase, and then subtracted from the first-bandpass-filtered signal, producing a signal in which substantially all distortion induced by filtering in the first bandpass filter is canceled. Bandpass filters having (i) low insertion loss and narrow bandwidth but (ii) high nonlinearity as induces distortion, notably of the high temperature superconductor types, may thus be used to better advantage, particularly in a power combining network of diplexor.

### REFERENCE TO A RELATED PATENT APPLICATION

The present patent application is related to U.S. patent application Ser. No. AAA,AAA filed on an even date herewith for a CIRCUIT AND METHOD IMPROVING LINEARITY, AND REDUCING DISTORTION, IN MICROWAVE RF BANDPASS FILTERS, ESPECIALLY SUPERCONDUCTING FILTERS to the selfsame inventors as is the present application. The content of the related patent application is incorporated herein by reference.

### BACKGROUND OF THE INVENTION

1. Field of the Invention

The present invention generally concerns microwave power combining circuits that typically serve to combine signals from a variety of narrowband sources—normally a number of power amplifiers each operating at a slightly different frequency—into a broadband signal that is typically transmitted through an antenna at a base station of a wireless communications network.

The present invention particularly concerns circuits and techniques for improving linearization, and reducing distortion, in the combining of narrowband signals, especially such combining as may transpire in a filter network made from high temperature superconductors.

2. Description of the Prior Art

One of the most important aspects of the implementation of a high performance base station for wireless communications applications is the combining of the signals from a variety of sources—each at a slightly different frequency—into a single broadband signal that is transmitted through the antenna.

The power combining network that accomplishes this is typically referred to as a diplexer. A diplexor is essentially a filter that presents a maximum power transfer input impedance match at its desired frequency, and a reactive match at all other frequencies. The resulting network, or diplexor, provides for an n-way power combining circuit, where each input is centered at a slightly different frequency from any of the others. In this way multiple signals can be combined in a frequency division duplexed system into a single antenna aperture.

One of the limitations of this approach is that the filters required to implement these power combining networks must possess an unusually narrow bandwidth and low insertion loss. These filter structures have historically been implemented in bulky and expensive waveguide structures. More recently, filters have been implemented in high-temperature thin-film superconductor technology, with an associated reduction in weight and cost. This new technology is a promising approach for the realization of improved frequency division duplexed systems.

However, thin-film superconductors exhibit relatively high nonlinearities, which limit the power levels that can be put through filters made of superconductors without incurring significant distortion. A new technique is required that will permit high power levels to be transmitted through these new superconductor filters without adding significant distortion products.

### SUMMARY OF THE INVENTION

The present invention contemplates a method, and a circuit, for combining microwave radio frequency (microwave rf) signals with improved linearization, and reduction of distortion. The invention is especially useful for use with existing narrowband filters that intrinsically have high distortion such as, at the present time (circa 1999), high temperature semiconductor (HTS) transmission line radio frequency (rf) filters that, although possessed of superior loss and noise characteristics, have undesirably large distortion.

The present invention employs a feed forward approach that substantially cancels out non-linearities in a power combining network, or diplexer. This cancellation permits, by way of example, that narrowband microwave rf signals may be combined in a filter network into a single broadband signal for transmission—most commonly from a base station of wireless communications network—with reduced distortion, and improved network performance.

1. High-Level Description of the Invention

In the reduced-distortion bandpass filtering circuit, and method, of the present invention a small portion—normally −20 db —of an input signal—normally a narrowband rf signal—is fed forward while a major portion of the same signal is filtered in a first bandpass filter, inducing distortion.

The small portion fed forward is itself bandpass filtered in a second bandpass filter, preferably a filter of identical construction to the first bandpass filter. However, because the signal level is lower, less distortion is produced.

Returning to the first-bandpass-filtered signal, yet another small—typically −20 db—portion of this signal, distortion and all, is again fed forward. This fed forward portion is subtracted from the second-bandpass-filtered signal, and vice versa, so that undistorted parts of the two signals cancel, isolating the signal distortion.

The isolated signal distortion is then amplified and adjusted in phase, and then subtracted from the first-bandpass-filtered signal. By appropriate control of signal phase and level, substantially all distortion induced by the filtering in the first bandpass filter is canceled.

This distortion cancellation by a feed forward linearization technique permits that bandpass filters of desirably low insertion loss and narrow bandwidth, but undesirably high nonlinearity such as induces distortion, may beneficially be used. Such bandpass filters notably include (circa 1999) those of the high temperature superconductor types.

The circuit and method of the present invention thus permits the beneficial use of highly nonlinear, signal-distortion-inducing, bandpass filters in a power combining network or diplexor, such as in the combination of multiple narrowband rf signal into a single broadband rf signal for transmission in a wireless radio communications network.

2. Intermediate Level Description of the Invention

In greater detail, the present invention may be considered to be embodied in a bandpass filtering method for producing a bandpass-filtered output signal from an input signal.

The bandpass filtering method commences by splitting (or first-coupling, if the reader prefers), in a first signal coupler, the input signal into a major portion and a minor portion. The minor signal portion is typically −20 db from the major signal portion.

The major portion of the input signal is first-bandpass-filtered, in a first bandpass filter having an inevitable first nonlinearity, to produce a first bandpass-filtered signal having an inevitable first distortion.

Meanwhile, the minor portion of the input signal is second-bandpass-filtered, in a second bandpass filter itself having an inevitable second nonlinearity, to produce a second bandpass-filtered signal having a second distortion. The second bandpass filter is preferably identical to the first bandpass filter. The second distortion is, however, much less than the first distortion because the power of the minor signal portion that is second-bandpass-filtered signal is much less than that of the major signal portion that is first-bandpass-filtered (and is typically −20 db less).

A small portion—preferably again about −20 db—of the first bandpass-filtered signal, distortion and all, is second-coupled by a second signal coupler to a first signal splitter. The second-bandpass-filtered signal is also input to this first signal splitter. Clearly both signals, each of which is about −20 db from the input signal (or first-bandpass-filtered input signal), are equal in magnitude.

This first signal splitter combines the second-coupled small portion of the first bandpass-filtered signal with the roughly equal magnitude second bandpass-filtered signal so that undistorted portions of both signals subtract and substantially cancel, leaving only a distorted signal portion.

This distorted signal portion is amplified in an amplifier, and phase shifting in a phase shifter, to produce an amplified phase-shifted distorted signal portion.

The amplified phase-shifted distorted signal portion is third coupled in a third coupler to the first-bandpass-filtered major portion of the input signal. This third coupling serves to substantially cancel the distortion in the (first) bandpass-filtered output signal.

3. A Detail Level Description of the Invention

In still greater detail, the present invention may be considered to be embodied in an improvement to a power combining network, or diplexor, that serves to combine in a plurality of nonlinear bandpass filters a plurality of input narrowband radio frequency signals into a corresponding plurality of bandpass-filtered narrowband radio frequency signals so as to produce in wired-OR combination a single output broadband radio frequency signal. In the improvement of the present invention each of the plurality of non-linear bandpass filters has additional parts, and circuit paths, beyond a mere bandpass filter.

A first signal coupler splits an input narrowband radio frequency signal into (i) a major first signal portion that is communicated along a first signal path and (ii) a minor second signal portion of lessor magnitude that is communicated along a second signal path.

The first signal path includes, in order (i) a bandpass filter, and (ii) two signal couplers.

Namely, a first bandpass filter—inevitably exhibiting a first-filter non-linearity—bandpass-filters the major first signal portion of the input narrowband radio frequency signal to produce a first-bandpass-filtered narrowband radio frequency signal. This first-bandpass-filtered narrowband radio frequency signal inevitably has, as result of non-linearity of the first bandpass filter 14, both an undistorted and an associated distorted part.

A signal coupler, the second overall, splits the first-bandpass-filtered narrowband radio frequency signal from the first bandpass filter into a major signal portion and a minor signal portion, each of which portions likewise has both undistorted and distorted parts.

A third signal splitter subtracts a specified signal—the origin of which is hereinafter explained—from the major signal portion of the first-bandpass-filtered narrowband radio frequency signal from the second signal coupler. This subtraction produce a bandpass-filtered narrowband radio frequency signal in which distortion is canceled.

This occurs because the second signal path includes, in order, (i) a combined phase shifter and bandpass filter, (ii) a signal splitter, and (iii) a combined amplifier and (yet another) phase shifter.

Namely, the second path commences with a combination of a first phase shifter and a second bandpass filter. The second bandpass filter, which is preferably identical to the first bandpass filter, bandpass-filters the second portion of the input narrowband radio frequency signal. The phase shifter and second bandpass filter jointly produce in combination a phase-reversed second-bandpass-filtered narrowband radio frequency signal. This signal inevitably has, as result of the non-linearity of the second bandpass filter, both non-distorted and associated distorted parts. However, because the minor second signal portion is of lessor magnitude than is the major first signal portion, the distorted part of the phase-reversed second-bandpass-filtered narrowband radio frequency signal is of lessor magnitude than is the distorted part of the minor signal portion of the second signal coupler.

A first signal splitter combines the phase-reversed second-bandpass-filtered narrowband radio frequency signal from the combined phase reverser and second bandpass filter with the minor second signal portion from the second coupler. This combining is in a manner so as to substantially cancel non-distorted parts of both signals, whereas the unequal distorted parts of both signals result in a signal output from the signal splitter that is, effectively, the isolated distortion of the first-bandpass-filtered input signal.

This “distortion signal” is passed through a combination of an amplifier and a second phase shifter in either order. An amplified double-phase-reversed second-bandpass-filtered narrowband radio frequency signal is produced. This entire signal is substantially equal to the distorted part of the of the major signal portion from the second signal coupler.

Accordingly, the specified signal that is subtracted from the major signal portion in the third signal coupler is this amplified double-phase-reversed second-bandpass-filtered narrowband radio frequency signal. Since the distortion of these two signals are substantially equal, and of opposite phase, the coupling is a subtraction. The signal subtraction results in a substantial cancellation of distortion in the produced bandpass-filtered narrowband radio frequency signal.

These and other aspects and attributes of the present invention will become increasingly clear upon reference to the following drawings and accompanying specification.

### BRIEF DESCRIPTION OF THE DRAWINGS

FIG. 1 is a schematic diagram of a prior art microwave power combining network.

FIG. 2 is a schematic diagram of a bandpass filter circuit of the present invention.

### DESCRIPTION OF THE PREFERRED EMBODIMENT

The present invention is embodied in an improved linearization circuit, and technique, for the combining of narrowband microwave power signals, especially as are bandpass filtered in a combining filter network, or diplexor, using high temperature superconducting bandpass filters. The circuit, and technique, employs a novel feed forward approach that cancels out signal distortion due to nonlinearities in the bandpass filters. This distortion cancellation permits efficient combining of narrowband rf signals into a single broadband rf signal for transmission in a wireless network.

1. The General Structure and Purpose of a Microwave Power Combining Network

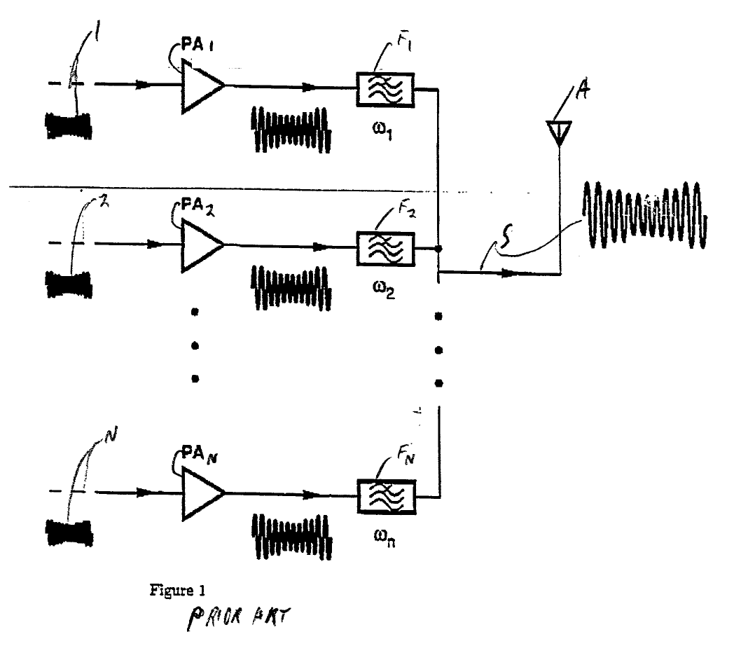

A schematic diagram of a prior art microwave power combining network is shown in FIG. 1. Narrowband radio frequency (rf) signals 1-N are respectively passed through power amplifiers PA₁, PA₂, . . . PA_{N} and associated narrowband filters F₁, F₂, . . . F_{N} to be wire-ORED together to form a broadband rf output signal S that is typically transmitted through an antenna A.

The prior art microwave power combining circuit of FIG. 1 thus serves to combine narrowband signals from a variety of sources —each at a slightly different frequency—into a single broadband signal 4 that is transmitted through the antenna 5. This power combining network is typically referred to as a diplexer. It essentially operates as a filter presenting a maximum power transfer impedance match at a desired frequency, and a reactive match at all other frequencies. The power combining circuit thus performs n-way power combining, where each input signal is centered at a slightly different frequency from any of the other input signals. In this way multiple signals can be combined in a frequency division multiplexed communication system into a single antenna aperture.

As explained in the BACKGROUND OF THE INVENTION section of this specification, a limitation of this approach is that the filters required to implement these power combining networks must possess an unusually narrow bandwidth and low insertion loss. Historically implemented in bulky and expensive waveguide structures, filters for microwave power combining networks have more recently been implemented in high-temperature thin-film superconductor technology, with an associated reduction in weight and cost. Alas, thin-film superconductors undesirably exhibit relatively high nonlinearities, which serves to limit the power levels that can be handled without incurring significant distortion. The present invention concerns a new technique in that it permits these new superconductor filters to be used to transmit high power levels without adding significant distortion products.

2. The Feed Forward Distortion Cancellation Circuit—Appropriate to an N-stage Power Narrowband RF Signal Combining Circuit, or Diplexor—of the Present Invention

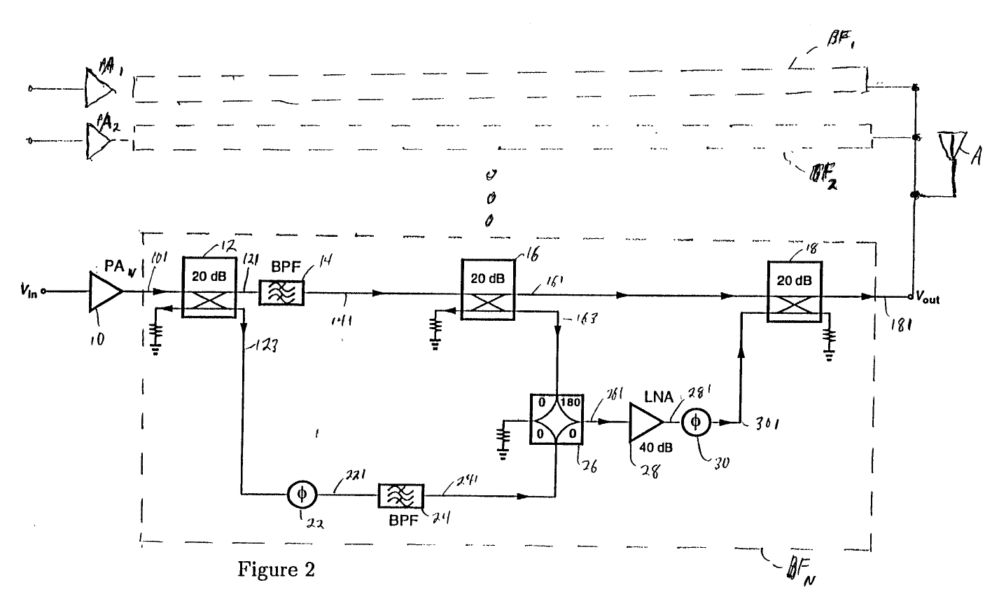

The preferred embodiment of a feed forward distortion cancellation circuit in accordance with the present invention is shown in FIG. 2. One of the new feed forward filter circuits, of which there are typically many each corresponding to single filter shown in FIG. 1, is illustrated expanded. It will be understood by a practitioner of the electronic circuit design arts that circuit shown expanded in FIG. 2 is but a single stage corresponding to one of the N stages of the power narrowband rf signal combining circuit, or diplexor, shown in FIG. 1.

3. A Top Level, Functional, Explanation of the Circuit of the Present Invention

Before commencing with the detail, circuit element by circuit element and signal path by signal path, explanation of the circuit of FIG. 2 in section 2 following, it may be useful to quickly review the FIG. 2 circuit at a top, functional, descriptive level.

In the FIG. 2 filter circuit of the present invention, an output of a power amplifier 10 is sent as an input signal 101 to a (first) superconducting bandpass filter 12, as before in FIG. 1, while, now, a small portion 123, 221 of this input signal is coupled into a second, identical, band-pass filter 24. The signal input 123, 221 to this second bandpass filter 24 is a significantly smaller than the signal input 121 to the first bandpass filter 14. As a result the signal output 241 of this second bandpass filter 24 exhibits significantly smaller distortion and intermodulation products.

Continuing in the circuit of FIG. 2, the signal output 141 of the first bandpass filter 14 is coupled by an identical microwave coupler 16 and subtracted in a signal splitter 26 from the signal output 241 of the second bandpass filter 24.

The resulting output of the subtraction in the signal splitter 26 has—ideally—completely canceled the desired components of the outputs of the first bandpass filter 14 and the second bandpass filter 24, leaving only the in-band intermodulation products in the band of interest.

These in-band intermodulation products can also be, and are, canceled. They are so canceled by subtraction in the microwave signal coupler 18 of the intermodulation products, appropriately scaled (and adjusted in phase) in amplifier 28 (and phase shifter 30). The intermodulation products at the signal output 181 of the entire filter network circuit are thus substantially canceled.

The narrowband rf bandpass filter circuit of FIG. 2 thus exhibits dramatically lower distortion, resulting in improved microwave performance for wireless base station applications.

The ability to achieve the intended distortion cancellation of the present invention is limited by the matching between the two bandpass filters 14, 24. In particular, the linear responses of these filters 14, 24 must be nearly identical in order to achieve the desired level of cancellation. If the linear responses are not equal across the band of interest, then the low-noise amplifier 28 will operate in a highly nonlinear fashion, resulting in less improvement in the overall circuit response.

The technique of the present invention is somewhat similar to the technique, taught in a related specification filed on the same date at the present specification, for the linearization of power amplifiers using a so-called feed-forward technique. However, this specification deals with the application of a feed-forward technique to filter linearization.

2. Detailed Explanation of the Circuit of the Present Invention

In detail, the circuit of the present invention—shown in expanded view in FIG. 2 as BF_{N} standing for “Bandpass Filter #N”—is useful in a power combining network, or diplexor, where a number of such bandpass filters BF₁-BF_{N} serve to bandpass filter a corresponding number N of narrowband radio frequency signals amplified in power amplifiers PA₁-PA_{N}, producing a corresponding number N of bandpass-filtered narrowband radio frequency signals. These signals are wired-OR together to produce a single output broadband radio frequency signal that may typically be broadcast through an antenna A.

In accordance with the present invention, each of the bandpass filters, of which Bandpass Filter BF_{N} is exemplary, includes a first signal coupler 12 that splits an input narrowband radio frequency signal 101 into a major first signal portion 121 communicated along a first signal path and a minor second signal portion 123 of lessor magnitude communicated along a second signal path. Typically minor signal portion 123 is −20 db relative to major signal portion 121, as indicated on the face of signal coupler 12 shown in FIG. 2.

The first signal path includes, in order, (a) a bandpass filter and (ii) two signal couplers.

Namely, a first bandpass filter 14, inevitably exhibiting a first-filter non-linearity, bandpass-filters the major first signal portion 121 of the input narrowband radio frequency signal 101 to produce a first-bandpass-filtered narrowband radio frequency signal 141. This first-bandpass-filtered narrowband radio frequency signal 141 inevitably has, as result of the inevitable non-linearity of the first bandpass filter 14, both an undistorted and an associated distorted part. In accordance with the present invention, the first bandpass filter 14 can be—but need not be—quite non-linear, and the distorted part of the first-bandpass-filtered narrowband radio frequency signal 141 can be quite large. It can be, for example, so large as to render the signal unsuitable of combination with like signal to produce a broadband rf signal suitable for broadcast in an effective cellular radio communications system.

A second signal coupler 16 splits the first-bandpass-filtered narrowband radio frequency signal 141 from the first bandpass filter 14 into a major signal portion 161 and a minor signal portion 163. Each of these signal portions 161, 163 likewise has both undistorted and distorted parts.

A third signal coupler 18 serves to subtract a specified signal from the major signal portion 161 of the first-bandpass-filtered narrowband radio frequency signal received from the second signal coupler 16 to produce a bandpass-filtered narrowband radio frequency signal 181. More will be described as to exactly what is subtracted, and what is produced thereby, momentarily.

Meanwhile, the second signal path includes, in order, (i) a combination of a phase shifter and a second bandpass filter, (ii) a first signal splitter, and (iii) a combination of an amplifier and a phase shifter.

The combination of a first phase shifter 22, and a second bandpass filter 24 serves to bandpass-filter the second portion 123 of the input narrowband radio frequency signal 101. The first phase shifter 22 and the second bandpass filter 24 are spoken of as being in “combination” because, quite clearly to a practitioner of the electrical circuit design arts, either element may be placed first (or second) in the signal path. The combined first phase shifter 22 and second bandpass filter 24 jointly produce a phase-reversed second-bandpass-filtered narrowband radio frequency signal 241. The nominal phase shift of this signal is 180°.

This phase-reversed second-bandpass-filtered narrowband radio frequency signal 241 inevitably has, as result of the inevitable non-linearity of the second bandpass filter 24, both non-distorted and associated distorted parts. However, because the minor second signal portion 123 is of much lessor magnitude than is the major first signal portion 121, the distorted part of the phase-reversed second-bandpass-filtered narrowband radio frequency signal 241 is also much, much less than the distorted part of the minor signal portion 163 of the second signal coupler 16. Indeed, it may be considered to be essentially zero.

A first signal splitter 26 combines (i) the phase-reversed second-bandpass-filtered narrowband radio frequency signal 241 from the combined phase reverser 22 and second bandpass filter 24 with (ii) the minor second signal portion 163 from the second coupler 16. Note that the minor signal portion 163 is −20 db of the major signal portion 161 by action of signal coupler 16 (as noted on the face of the signal coupler 16), and is thus of the same magnitude as is signal 241. This combining is in a manner so as to substantially cancel non-distorted parts of both signals 241, 163 while the difference between the greatly unequal distorted parts of both signals 241, 163 remains a signal output from the first signal splitter 26, which signal output 261 is called a “distortion signal”.

This signal 261 is received into a combination of a low noise amplifier 28 and second phase shifter 30. Again, it matters not which of these circuit elements is first, and which is second. The phase shifter 30 commonly produces a phase shift of only a few degrees, and is used to “tune” the overall bandpass filter BP_{N}. Indeed, a practitioner in the electronic circuit design arts will recognize that the entire bandpass filter circuit (and, indeed, the combined bandpass filter circuits) have to be both tuned and balanced, and this is routine in the art. The low noise amplifier 28 may be, in particular, variably adjustable in gain.

The low noise amplifier 28 and second phase shifter 30 jointly produce an amplified double-phase-reversed second-bandpass-filtered narrowband radio frequency signal 301, which signal has a distorted part substantially equal to the distorted part of the major signal portion 163 of the second signal coupler 16. To a practitioner of the electronic circuit design arts, this equivalence simply means that the amplifier 28 boosts the signal by 40 db, and this is so labeled in FIG. 2.

Thus the “specified signal” —referred to in the seventh paragraph above—that is subtracted from the major signal portion 161 in the third signal coupler 18 is the amplified double-phase-reversed second-bandpass-filtered narrowband radio frequency signal 301. Since the distortion of these two signals is substantially equal, the subtraction results in a substantial cancellation of distortion in the produced bandpass-filtered narrowband radio frequency signal 181.

5. Advantages of The Present Invention Over Previous Approaches

A considerable portion of the utility of the present invention arises from revolutionary technical developments in other technology areas. In particular, the advent of high-quality thin-film high-temperature superconductors has now, circa 1999, made the realization of low volume high-quality filters practical for the first time. However, the application of these new filters to the well-known problem of power combining has been limited by the relatively poor linearity of the filters themselves. Existing techniques—using bulky cavity resonators—do not suffer from these linearity problems due to the fact that they rely on non-superconducting metallization, which is itself almost ideally linear.

The technique of the present invention is in some ways similar to traditional power amplifier linearization techniques using feed forward cancellation approaches. However, the application of the approach of the present invention to filter linearization, particularly for power combining applications, is believed by the inventors to be unique.

In accordance with the preceding explanation, variations and adaptations of the a feed-forward bandpass filter circuit, and method, in accordance with the present invention will suggest themselves to a practitioner of the electronic circuit design arts. For example, such phase reversal(s) as is (are) required can sometimes be incorporated in other circuit elements, or realized by the polarity with which signals are coupled to these elements. In interpreting the following claims the essential elements, couplings and feed-forward circuit are clear, and no undue reliance should be made on the fact that a signal may be, for clarity and completeness, described as “substantially equal” or “phase reversed” when a practitioner will realize that such niceties of circuit construction are readily adjustable, and may be compensated for at various points both early and late in various signal paths.

In accordance with these and other possible variations and adaptations of the present invention, the scope of the invention should be determined in accordance with the following claims, only, and not solely in accordance with that embodiment within which the invention has been taught.

What is claimed is:

1. A reduced-distortion method of bandpass filtering an input signal comprising:
feeding forward a first portion of an input signal; while
first-bandpass-filtering a major portion of the same input signal in a first bandpass filter, inducing thereby a first distortion; and
second-bandpass-filtering the fed forward small portion of the input signal in a second bandpass filter, inducing thereby a second distortion which second distortion is, however, lower than the first distortion induced in the first-bandpass-filtered signal because the power of the small portion of the input signal is lower than that of the major portion of the same input signal;
feeding forward a small portion of the first-bandpass-filtered signal, first distortion and all;
first subtracting this (i) fed-forward portion of the first-bandpass-filtered signal from (ii) the second-bandpass-filtered signal, therein substantially canceling undistorted parts of the two signals and producing a composite signal in which composite signal distortion is substantially isolated;
amplifying the composite signal, and adjusting it in phase; and then
second-subtracting the amplified phase-adjusted composite signal from the first-bandpass-filtered signal so as to substantially cancel in this first-bandpass-filtered signal the first distortion that was induced by the first-bandpass-filtering, producing thereby a reduced-distortion bandpass-filtered signal.

2. The bandpass filtering method according to claim 1
wherein the first-bandpass-filtering transpires in a first bandpass filter of identical construction to the second bandpass filter in which the second-bandpass-filtering transpires.

3. The bandpass filtering method according to claim 1
wherein the first-bandpass-filtering and the second-bandpass-filtering transpire in bandpass filters of the high temperature superconductor type.

4. The bandpass filtering method according to claim 1 performed in parallel on a plurality of narrowband input signals to produce a plurality of reduced-distortion bandpass-filtered signals each of which is narrowband, the method further comprising:
combining the plural narrowband reduced-distortion bandpass-filtered signals into a broadband signal.

5. A circuit for bandpass filtering an input signal comprising:
a first coupler feeding forward a small first portion of the input signal;
a first bandpass filter first-bandpass-filtering a major portion of the same input signal, inducing first distortion in the first-bandpass-filtered signal; and
a second bandpass filter second-bandpass-filtering the fed forward small portion of the input signal, inducing second distortion which second distortion is, however, lower than the first distortion induced in the first-bandpass-filtered signal by the first bandpass filter because the power of the small portion of the input signal is lower than that of the major portion of the input signal;
a second coupler feeding forward a small portion of the first-bandpass-filtered signal, first distortion and all;
a first subtractor first-subtracting this (i) fed-forward portion of the first-bandpass-filtered signal from (ii) the second-bandpass-filtered signal, therein substantially canceling undistorted parts of the two signals and producing a composite signal in which composite signal distortion is substantially isolated;
an amplifier/phase shifter amplifying the composite signal and adjusting it in phase; and
a second subtractor second-subtracting the amplified phase-adjusted composite signal from the first-bandpass-filtered signal so as to substantially cancel in the first-bandpass-filtered signal the first distortion that was induced by the first-bandpass-filter, producing thereby a reduced-distortion bandpass-filtered signal.

6. The circuit according to claim 5
wherein the first bandpass filter is of identical construction to the second bandpass filter.

7. The circuit according to claim 5 wherein the first bandpass filter and the second bandpass filter each comprise:
a high temperature superconductor filter.

8. In a power combining network, or diplexor, serving to combine in a plurality of non-linear bandpass filters a plurality of input narrowband radio frequency signals into a corresponding plurality of bandpass-filtered narrowband radio frequency signals to produce in wired-OR combination a single output broadband radio frequency signal, an improvement wherein each of the plurality of non-linear bandpass filters comprises:
a first signal coupler 12 splitting an input narrowband radio frequency signal 101 into a major first signal portion 121 communicated along a first signal path and a minor second signal portion 123 of lessor magnitude communicated along a second signal path;
the first signal path including in order
a first bandpass filter 14, inevitably exhibiting a first-filter non-linearity, bandpass-filtering the major first signal portion 121 of the input narrowband radio frequency signal 101 to produce a first-bandpass-filtered narrowband radio frequency signal 141 inevitably having, as result of non-linearity of the first bandpass filter 14, both an undistorted and an associated distorted part,
a second signal coupler 16 splitting the first-bandpass-filtered narrowband radio frequency signal 141 from the first bandpass filter 14 into a major signal portion 161 and a minor signal portion 163 likewise each having undistorted and distorted parts, and
a third signal coupler 18 subtracting a specified signal from the major signal portion 161 of the first-bandpass-filtered narrowband radio frequency signal from the second signal coupler 16 to produce a bandpass-filtered narrowband radio frequency signal 181; and
the second signal path including in order
a combination of
a first phase shifter 22, and
a second bandpass filter 24 bandpass-filtering the second portion 123 of the input narrowband radio frequency signal 101,
jointly producing a phase-reversed second-bandpass-filtered narrowband radio frequency signal 241 inevitably having, as result of the non-linearity of the second bandpass filter 24, both non-distorted and associated distorted parts,
wherein, because the minor second signal portion 123 is of lessor magnitude than is the major first signal portion 121, the distorted part of the phase-reversed second-bandpass-filtered narrowband radio frequency signal 241 is less than the distorted part of the minor signal portion 163 of the second signal coupler 16, and
a first signal splitter 26 combining the phase-reversed second-bandpass-filtered narrowband radio frequency signal 241 from the combined phase reverser 22 and second bandpass filter 24 with the minor second signal portion 163 from the second coupler 16 in a manner so as to substantially cancel non-distorted parts of both signals 241, 163 while the unequal distorted parts of both signals 241, 163 serve to produce a signal output from the first signal splitter that is called a distortion signal, and
a combination of
an amplifier, and
a second phase shifter;
jointly producing an amplified double-phase-reversed second-bandpass-filtered narrowband radio frequency signal 301 having a distorted part substantially equal to the distorted part of the major signal portion 163 of the second signal coupler 16;
wherein the specified signal subtracted from the major signal portion 161 in the third signal coupler 18 is the amplified double-phase-reversed second-bandpass-filtered narrowband radio frequency signal 301, and since the distortion of these two signals are substantially equal, the subtraction results in a substantial cancellation of distortion in the produced bandpass-filtered narrowband radio frequency signal 181.

9. The improvement to a power combining network according to claim 8
wherein the second bandpass filter 24 has a non-linearity equalling insofar as is possible the non-linearity of the first bandpass filter 14.

10. The improvement to a power combining network according to claim 8 wherein the first phase shifter comprises:
a phase reverser.

11. The improvement to a power combining network according to claim 8 wherein the second phase shifter is adjustable in phase shift;
wherein by adjustment of the cancellation of distortion in the third coupler may be optimized on conditions.

12. The improvement to a power combining network according to claim 8 wherein the first bandpass filter comprises:
a superconductor transmission line.

13. The improvement to a power combining network according to claim 8 wherein the second bandpass filter comprises:
a superconductor transmission line.

14. A bandpass filtering method for producing a bandpass-filtered output signal from an input signal, the bandpass filtering method comprising:
splitting in a first coupler the input signal into a major portion and a minor portion;
first-bandpass-filtering, in a first bandpass filter having an inevitable first nonlinearity, the major portion of the input signal to produce therefrom a first bandpass-filtered signal having inevitable first distortion;
second-bandpass-filtering, in a second bandpass filter having an inevitable second nonlinearity, the minor portion of the input signal to produce therefrom a second bandpass-filtered signal having a second distortion that is, although inevitable, much less than the first distortion of the first bandpass-filtered signal;
coupling in a second coupler a small portion of the first bandpass-filtered signal, distortion and all, that is roughly equal in magnitude to the second bandpass-filtered signal;
combining in a first signal splitter the second-coupled small portion of the first bandpass-filtered signal with the roughly equal magnitude second bandpass-filtered signal so that undistorted portions of the signal subtract and substantially cancel, leaving only a distorted signal portion;
amplifying in an amplifier, and phase shifting in a phase shifter, the distorted signal portion to produce an amplified phase-shifted distorted signal portion; and
coupling in a third coupler the amplified phase-shifted distorted signal portion to a major portion of the input signal so that a bandpass-filter output signal wherein distortion is substantially canceled is produced.

15. A reduced-distortion bandpass filtering method comprising:
first bandpass filtering in a distortion-inducing first bandpass filter an input signal to produce a first-bandpass-filtered input signal having a first distortion;
first feeding forward in a first signal coupler a small portion of the input signal;
second bandpass filtering in a distortion-inducing second bandpass filter the first-fed-forward small portion of the input signal to produce a second-bandpass-filtered input signal having a second distortion much less than the first distortion;
second feeding forward in a second signal coupler a small portion of the first-bandpass-filtered input signal, first distortion and all;
subtracting in a first signal splitter the second-bandpass-filtered input signal from the second-fed-forward small portion of the first-bandpass-filtered input signal to produce a distortion correction signal;
amplifying the distortion correction signal to produce an amplified distortion correction signal; and
coupling in a third signal splitter the first-bandpass-filtered input signal to the distortion correction signal so as to substantially cancel first distortion in the first-bandpass-filtered input signal;
wherein by action of the coupling distortion arising from the first bandpass filtering is reduced.

16. A reduced-distortion bandpass filtering circuit comprising:
a first signal coupler 12 feeding forward a minor portion 123 of an unfiltered input signal 101 while communicating a major portion 121 of this signal to
a first bandpass filter 14 performing bandpass filtering on the major portion 121 of the input signal 101, producing a first-bandpass-filtered signal 141 having distortion;
a second bandpass filter 24 performing bandpass filtering on the fed forward minor portion 123 of the input signal 101, producing a second-bandpass-filtered signal 241 having, because the signal level is lower, less distortion than does the first-bandpass-filtered signal 141;
a second signal coupler 16 feeding forward a minor portion 163 of the first-bandpass-filtered signal 141, distortion and all, while communicating a major portion 161 of this signal to
a third signal coupler 18;
a signal splitter 26 subtracting the fed forward minor portion 163 of the first-bandpass-filtered signal 141 from the second-bandpass-filtered signal 241 so that undistorted parts of the two signals 163, 241 cancel, leaving in isolation a signal 261 that represents the distortion of the first-bandpass-filtering; and
an amplifier 28 and phase adjuster 30 amplifying and adjusting in phase the signal 261 representing distortion to produce and amplified and phase-adjusted distortion signal 301;
wherein the third signal coupler 18 subtracts this amplified and phase-adjusted distortion signal 301 from the major portion 161 of the first-bandpass-filtered signal 141, canceling distortion in the first-bandpass-filtered signal 141 induced by the first-bandpass-filtering in the first bandpass filter 14.
